(19) United States
(12) Patent Application Publication
(10) Pub. No.: US 2024/0099077 A1
(43) Pub. Date: Mar. 21, 2024

(54) DISPLAY APPARATUS

(71) Applicant: SAMSUNG DISPLAY CO., LTD., Yongin-si (KR)

(72) Inventors: Hyeonsik KIM, Yongin-si (KR); Yoolguk KIM, Yongin-si (KR); Jiyoon KIM, Yongin-si (KR); Jaehyun PARK, Yongin-si (KR); Heewoon IM, Yongin-si (KR)

(21) Appl. No.: 18/124,988

(22) Filed: Mar. 22, 2023

(30) Foreign Application Priority Data
Sep. 15, 2022 (KR) 10-2022-0116636

(51) Int. Cl. H10K 59/124; H10K 59/122; H10K 59/80

(52) U.S. Cl. CPC H10K 59/124; H10K 59/122; H10K 59/80515

(57) ABSTRACT

A display apparatus includes a substrate, a pixel circuit disposed on the substrate, a planarization insulating layer disposed on the pixel circuit and including a first structure including an opening or a groove, a bank layer disposed on the planarization insulating layer and including a first opening overlapping the first structure, and an intermediate layer disposed in at least a portion of the first structure and the first opening.

This application claims priority to Korean Patent Application No. 10-2022-0116636, filed on Sep. 15, 2022, and all the benefits accruing therefrom under 35 U.S.C. § 119, the content of which in its entirety is herein incorporated by reference.

### BACKGROUND

### 1. Field

Embodiments relate to an apparatus, and more particularly, to a display apparatus.

### 2. Description of the Related Art

Mobile electronic apparatuses are widely used. Recently, tablet personal computers have become widely used, as well as miniaturized electronic apparatuses such as mobile phones.

To support various functions, e.g., to provide a user with visual information, such as images, the mobile electronic apparatuses include a display apparatus. Recently, as the parts driving a display apparatus are being miniaturized, a proportion of the display apparatus in an electronic apparatus is gradually increasing and a structure that may be bent to have a preset angle with respect to a flat state is also under development.

### SUMMARY

Embodiments include a display apparatus which additionally secures a space in which an intermediate layer may be disposed by disposing an opening or a groove in a planarization insulating layer, and arranging the space, a pixel circuit, and other wirings disposed in the intermediate layer to be spaced apart from one another in a plan view.

However, such a technical problem is an example, and the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a substrate, a pixel circuit disposed on the substrate, a planarization insulating layer which is disposed on the pixel circuit and including a first structure in which an opening or a groove is defined, a bank layer disposed on the planarization insulating layer and including a first opening overlapping the first structure, and an intermediate layer disposed in at least a portion of the first structure and the first opening.

In an embodiment, the first structure and the first opening may be spaced apart from the pixel circuit in a plan view.

In an embodiment, the planarization insulating layer may include a first planarization insulating layer, and a second planarization insulating layer on the first planarization insulating layer.

In an embodiment, a first groove may be defined in the second planarization insulating layer in the first structure.

In an embodiment, a second opening may be defined in the second planarization insulating layer in the first structure.

In an embodiment, a second groove overlapping the second opening may be defined in the first planarization insulating layer in the first structure.

In an embodiment, a third opening overlapping the second opening may be defined in the first planarization insulating layer in the first structure.

In an embodiment, the display apparatus may further include a first electrode connected to the intermediate layer and including at least a portion disposed between the second planarization insulating layer and the bank layer, and a contact metal connecting the first electrode to the pixel circuit and including at least a portion disposed between the first planarization insulating layer and the second planarization insulating layer. The first structure and the first opening may be spaced apart from the contact metal in a plan view.

In an embodiment, the planarization insulating layer may further include a third planarization insulating layer on the second planarization insulating layer.

In an embodiment, a fourth opening may be defined in the third planarization insulating layer in the first structure.

In an embodiment of the disclosure, a display apparatus includes a substrate, a pixel circuit disposed on the substrate, a planarization insulating layer disposed on the pixel circuit, a bank layer disposed on the planarization insulating layer, and an intermediate layer disposed in a first space disposed in the planarization insulating layer and the bank layer.

In an embodiment, the first space may be spaced apart from the pixel circuit in a plan view.

In an embodiment, the planarization insulating layer may include a first planarization insulating layer, and a second planarization insulating layer on the first planarization insulating layer.

In an embodiment, the first space may include a first opening defined in the bank layer, and a first groove overlapping the first opening and defined in the second planarization insulating layer.

In an embodiment, the first space may include the first opening defined in the bank layer, and a second opening overlapping the first opening and defined in the second planarization insulating layer.

In an embodiment, the first space may further include a second groove overlapping the second opening and disposed in the first planarization insulating layer.

In an embodiment, the first space may further include a third opening overlapping the second opening and disposed in the first planarization insulating layer.

In an embodiment, the planarization insulating layer may further include a third planarization insulating layer on the second planarization insulating layer.

In an embodiment, the first space may include a first opening defined in the bank layer, and a fourth opening overlapping the first opening and defined in the third planarization insulating layer.

In an embodiment, the display apparatus may further include a first electrode connected to the intermediate layer and including at least a portion disposed between the second planarization insulating layer and the bank layer, and a contact metal connecting the first electrode to the pixel circuit and including at least a portion disposed between the first planarization insulating layer and the second planarization insulating layer. The first space may be spaced apart from the contact metal in a plan view.

These and/or other features will become apparent and more readily appreciated from the following detailed description of the embodiments, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of a display apparatus;

FIG. 2 is a cross-sectional view of an embodiment of the display apparatus, taken along line II-II′ of FIG. 1.

FIG. 3 is an enlarged view of an embodiment of a region A of FIG. 2;

FIG. 4 is an enlarged view of another embodiment of a region A of FIG. 2;

FIG. 5 is an enlarged view of another embodiment of the region A of FIG. 2;

FIG. 6 is an enlarged view of another embodiment of the region A of FIG. 2;

FIG. 7 is an enlarged view of another embodiment of the region A of FIG. 2;

FIG. 8 is an equivalent circuit diagram of an embodiment of a pixel of the display apparatus;

FIG. 9 is a cross-sectional view of another embodiment of a display apparatus, taken along line II-II′; and

FIG. 10 is an enlarged view of an embodiment of a region B of FIG. 9.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. In an embodiment, the size and thickness of each element shown in the drawings are arbitrarily represented for convenience of description, and thus, the disclosure is not necessarily limited thereto.

The x-axis, the y-axis and the z-axis are not limited to three axes of the quadrangular (e.g., rectangular) coordinate system, and may be interpreted in a broader sense. In an embodiment, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

In the case where an illustrative embodiment may be implemented differently, a predetermined process order may be performed in the order different from the described order. In an embodiment, two processes successively described may be simultaneously performed substantially and performed in the opposite order.

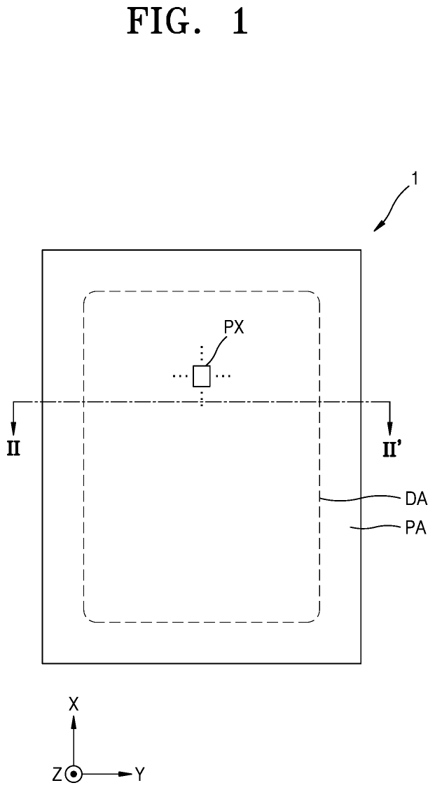

FIG. 1 is a schematic plan view of an embodiment of a display apparatus 1.

Referring to FIG. 1, the display apparatus 1 may include a display area DA and a peripheral area PA outside the display area DA. The display apparatus 1 may display images through an array of a plurality of pixels arranged two-dimensionally in the display area DA.

The peripheral area PA is a region that does not display images and may surround an entirety or a portion of the display area DA. A driver or the like which provides electric signals or power to pixel circuits respectively corresponding to the pixels may be arranged in the peripheral area PA. A pad may be disposed in the peripheral area PA, and the pad is a region to which electronic elements or a printed circuit board may be electrically connected.

Hereinafter, though the display apparatus 1 includes an organic light-emitting diode OLED as a light-emitting element, the display apparatus 1 according to the disclosure is not limited thereto. In another embodiment, the display apparatus 1 may be a light-emitting display apparatus including an inorganic light-emitting diode, that is, an inorganic light-emitting display apparatus. The inorganic light-emitting diode may include a PN diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width in the range of several micrometers to hundreds of micrometers. In an embodiment, the inorganic light-emitting diode may be denoted by a micro light-emitting diode. In another embodiment, the display apparatus 1 may be a quantum-dot light-emitting display apparatus.

The display apparatus 1 may be used as a display screen in various products including televisions, notebook computers, monitors, advertisement boards, Internet of things (IoTs) apparatuses as well as portable electronic apparatuses including mobile phones, smart phones, tablet personal computers, mobile communication terminals, electronic organizers, electronic books, portable multimedia players (“PMPs”), navigations, and ultra-mobile personal computers (“UMPCs”). In addition, the display apparatus 1 in an embodiment may be used in wearable devices including smartwatches, watchphones, glasses-type displays, and head-mounted displays (“HMDs”). In addition, in an embodiment, the display apparatus 1 is used as a display screen in instrument panels for automobiles, center fascias for automobiles, or center information displays (“CIDs”) arranged on a dashboard, room mirror displays that replace side mirrors of automobiles, and displays arranged on the backside of front seats as entertainment for passengers in back seats of automobiles.

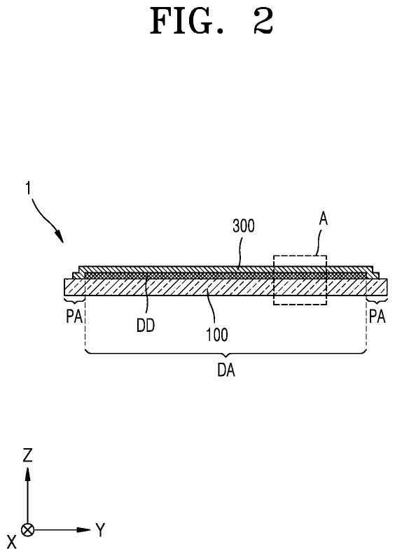

FIG. 2 is a cross-sectional view of an embodiment of the display apparatus 1, taken along line II-II′ of FIG. 1.

Referring to FIG. 2, the display apparatus 1 may include a substrate 100, a display portion DD, and an encapsulation layer 300.

The display portion DD may be disposed on the substrate 100 in the display area DA of the display apparatus 1. The encapsulation layer 300 may cover the display portion DD. The encapsulation layer 300 may contact the upper surface (e.g., a surface facing a +Z axis) of the display portion DD in the display area DA of the display apparatus 1. In addition, the encapsulation layer 300 may contact the upper surface (e.g., a surface facing a +Z axis) of the substrate 100 in the peripheral area PA of the display apparatus 1. The encapsulation layer 300 may cover the display portion DD and thus prevent external moisture and oxygen from penetrating the display portion DD.

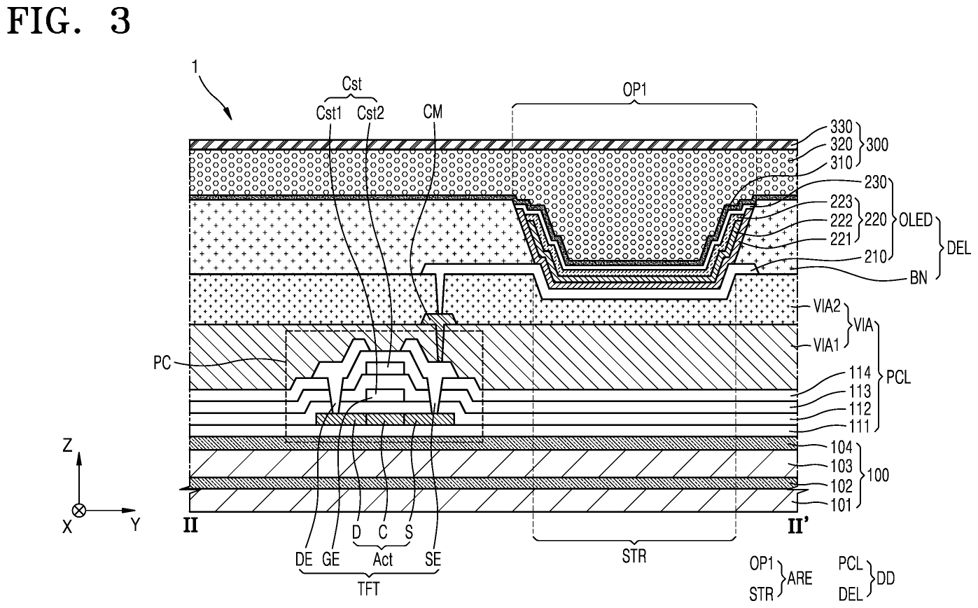

FIG. 3 is an enlarged view of an embodiment of a region A of FIG. 2.

Referring to FIG. 3, the display apparatus 1 may include a stack structure of the substrate 100, the display portion DD, and the encapsulation layer 300.

The substrate 100 may have a multi-layered structure including a base layer that includes polymer resin and an inorganic layer. In an embodiment, the substrate 100 may include the base layer including the polymer resin and a barrier layer including an inorganic insulating layer. In an embodiment, the substrate 100 may include a first base layer 101, a first barrier layer 102, a second base layer 103, and a second barrier layer 104 that are sequentially stacked. The first base layer 101 and the second base layer 103 may each include polyimide (“PI”), polyethersulfone (“PES”), polyacrylate, polyetherimide (“PEI”), polyethylene naphthalate (“PEN”), polyethylene terephthalate (“PET”), polyphenylene sulfide (“PPS”), polycarbonate, cellulose tri acetate (“TAC”), and/or cellulose acetate propionate (“CAP”). The first barrier layer 102 and the second barrier layer 104 may each include an inorganic insulating material such as silicon oxide, silicon oxynitride, and/or silicon nitride. The substrate 100 may be flexible.

The display portion DD may include a pixel circuit layer PCL and a display element layer DEL. The pixel circuit layer PCL may be disposed on the substrate 100.

The pixel circuit layer PCL may include a thin-film transistor TFT, a buffer layer 111, a first gate insulating layer 112, a second gate insulating layer 113, an inter-insulating layer 114, and a planarization insulating layer VIA under and/or on elements of the thin-film transistor TFT. FIG. 3 shows one of a plurality of thin-film transistors TFTs included in the pixel circuit PC.

The buffer layer 111 may reduce or block foreign materials, moisture, or external air penetrating from below the substrate 100 and may provide a flat surface on the substrate 100. The buffer layer 111 may include an inorganic insulating material such as silicon nitride, silicon oxynitride, or silicon oxide, and include a single-layered structure or a multi-layered structure including the above materials.

The thin-film transistor TFT on the buffer layer 111 may include a semiconductor layer Act, and the semiconductor layer Act may include polycrystalline silicon (poly-Si). In an alternative embodiment, the semiconductor layer Act may include amorphous silicon (a-Si), an oxide semiconductor, or an organic semiconductor. The semiconductor layer Act may include a channel region C, a drain region D, and a source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti) and have a single-layered structure or a multi-layered structure including the above materials.

The first gate insulating layer 112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

An upper electrode Cst2 of the storage capacitor Cst may be disposed on the second gate insulating layer 113. The upper electrode Cst2 may overlap the gate electrode GE therebelow. In this case, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

As described above, the storage capacitor Cst may overlap the thin-film transistor TFT. In an embodiment, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The inter-insulating layer 114 may cover the upper electrode Cst2. The inter-insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The inter-insulating layer 114 may include a single layer or a multi-layer including the inorganic insulating material.

The drain electrode DE and the source electrode SE may each be disposed on the inter-insulating layer 114. The drain electrode DE and the source electrode SE may be respectively connected to the drain region D and the source region S through contact holes of insulating layers therebelow. The drain electrode DE and the source electrode SE may each include a material having substantially high conductivity. The drain electrode DE and the source electrode SE may each include a conductive material including molybdenum (Mo), aluminum (Al), copper (Cu), and titanium (Ti) and include a single layer or a multi-layer including the above materials. In an embodiment, the drain electrode DE and the source electrode SE may each have a multi-layered structure of Ti/Al/Ti.

The planarization insulating layer VIA may cover the drain electrode DE and the source electrode SE. The planarization insulating layer VIA may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or any combinations thereof. The planarization insulating layer VIA may include a first planarization insulating layer VIA1 and a second planarization insulating layer VIA2. The second planarization insulating layer VIA2 may be disposed on the first planarization insulating layer VIA1.

The display element layer DEL may be disposed on the pixel circuit layer PCL having the above structure. The display element layer DEL may include a bank layer BN and an organic light-emitting diode OLED.

The bank layer BN may be disposed on the planarization insulating layer VIA. At least a portion of the bank layer BN may contact the second planarization insulating layer VIA2. The bank layer BN may include an organic insulating material and/or an inorganic insulating material.

A first space ARE may be disposed in the planarization insulating layer VIA and the bank layer BN. The planarization insulating layer VIA may include a first structure STR in which an opening or a groove is defined. Here, a term “an opening of an element” may refer to a recess passing through the element while a term “a groove” may mean a recess defined only in a portion of the element. In an embodiment, as shown in FIG. 3, the first structure STR may include a first groove defined in the second planarization insulating layer VIA2. That is, the first structure STR may be formed by collapsing from the second planarization insulating layer VIA2. A first opening OP1 overlapping the first structure STR may be defined in the bank layer BN. That is, the first space ARE may include the first structure STR and the first opening OP1.

At least a portion of the organic light-emitting diode OLED may be disposed in the first space ARE. The first space ARE may define an emission area of light emitted from the organic light-emitting diode OLED. In an embodiment, the size/width of the first space ARE may correspond to the size/width of the emission area. Accordingly, the size/width of the pixel may depend on the size/width of the first space ARE.

The organic light-emitting diode OLED may have a stack structure of a first electrode 210, an intermediate layer 220, and a second electrode 230. The organic light-emitting diode OLED may emit various color lights such as red, green, or blue light, or emit red, green, blue, or white light. The organic light-emitting diode OLED may emit light through an emission area. The emission area may be defined as a pixel.

The first electrode 210 may be disposed on the planarization insulating layer VIA and may overlap the first structure STR. The first electrode 210 may be connected to the intermediate layer 220, and at least a portion of the first electrode 210 may be disposed between the second planarization insulating layer VIA2 and the bank layer BN. A contact metal CM may connect the first electrode 210 to the pixel circuit PC. At least a portion of the contact metal CM may be disposed between the first planarization insulating layer VIA1 and the second planarization insulating layer VIA2. The contact metal CM may be connected to the pixel circuit PC through a contact hole defined in the first planarization insulating layer VIA1. The contact metal CM may be connected to the first electrode 210 through a contact hole defined in the second planarization insulating layer VIA2. Consequently, the contact metal CM may connect the first electrode 210 to the pixel circuit PC.

The first electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. In another embodiment, the first electrode 210 may further include a layer including ITO, IZO, ZnO, or In₂O₃ on/under the reflective layer.

The intermediate layer 220 may be disposed in the first space ARE. That is, the intermediate layer 220 may be disposed in at least a portion of the first structure STR and the first opening OP1. The intermediate layer 220 may include an emission layer 222 corresponding to the first electrode 210. The emission layer 222 may include a polymer organic material or a low-molecular weight organic material emitting light having a preset color. In an alternative embodiment, the emission layer 222 may include an inorganic emission material or quantum dots.

In an embodiment, the intermediate layer 220 may further include a first functional layer 221 and a second functional layer 223 respectively disposed under and on the emission layer 222. The first functional layer 221 may include a hole transport layer (“HTL”), or include an HTL and a hole injection layer (“HIL”), for example. The second functional layer 223 is an element disposed on the emission layer 222 and may include an electron transport layer (“ETU”) and/or an electron injection layer (“EIL”).

As shown in FIG. 3, like the second electrode 230 described below, the first functional layer 221 and the second functional layer 223 may be disposed only inside the first space ARE. However, this is an example, and the first functional layer 221, the second functional layer 223, and the second electrode 230 may be common layers covering an entirety of the substrate 100.

The second electrode 230 may be disposed over the first electrode 210 and may overlap the first electrode 210. At least a portion of the second electrode 230 may be disposed on the intermediate layer 220. That is, the intermediate layer 220 may be disposed between the first electrode 210 and the second electrode 230.

The second electrode 230 may include a conductive material having a substantially low work function. In an embodiment, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or any alloys thereof. In an alternative embodiment, the second electrode 230 may further include a layer on the (semi) transparent layer, the layer including ITO, IZO, ZnO, or In₂O₃.

The height of the first space ARE may be secured by the first structure STR of the planarization insulating layer VIA. Accordingly, during a process of disposing the intermediate layer 220 in the first space ARE, a phenomenon in which the intermediate layer 220 overflows from the first space ARE may be reduced. In an embodiment, a color mixing phenomenon in which the emission layers 222 which emit light of different colors overflow from the first space ARE and the colors are mixed may be reduced. In an embodiment, the height of the first space ARE may be about 5 micrometer (μm) or more. That is, a sum of the height of the first structure STR and the height of the first opening OP1 may be about 5 μm or more. However, this is only one of embodiments, and the height of the first space ARE is not limited thereto.

The first space ARE may be spaced apart from the pixel circuit PC and the contact metal CM in a plan view. That is, the first space ARE may not overlap the pixel circuit PC and the contact metal CM. The first structure STR and the first opening OP1 may be spaced apart from the pixel circuit PC and the contact metal CM in a plan view. That is, the first structure STR and the first opening OP1 may not overlap the pixel circuit PC and the contact metal CM. In this structure, a phenomenon in which the flatness of the first electrode 210 overlapping the intermediate layer 220 is reduced due to the pixel circuit PC and the contact metal CM, and other wirings may be reduced.

The encapsulation layer 300 may be disposed on the display element layer DEL and may cover the display element layer DEL. The encapsulation layer 300 may include at least one inorganic encapsulation layer and at least one organic encapsulation layer. In an embodiment, it is shown in FIG. 3 that the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, or polyethylene. In an embodiment, the organic encapsulation layer 320 may include acrylate. The organic encapsulation layer 320 may be formed by curing a monomer or coating a polymer. The organic encapsulation layer 320 may be transparent.

Though not shown, a touch sensor layer may be disposed on the encapsulation layer 300. An optical functional layer may be disposed on the touch sensor layer. The touch sensor layer may obtain coordinate information corresponding to an external input, e.g., a touch event. The optical functional layer may reduce the reflectivity of light (external light) incident toward the display apparatus from outside, and/or improve the color purity of light emitted from the display apparatus. In an embodiment, the optical functional layer may include a retarder and/or a polarizer. The retarder may include a film-type retarder or a liquid crystal-type retarder. The retarder may include a λ/2 retarder and/or a λ/4 retarder. The polarizer may include a film-type polarizer or a liquid crystal-type polarizer. The film-type polarizer may include a stretchable synthetic resin film, and the liquid crystal-type polarizer may include liquid crystals arranged in a predetermined arrangement. Each of the retarder and the polarizer may further include a protective film.

An adhesive member may be disposed between the touch sensor layer and the optical functional layer. For the adhesive member, a general adhesive member known in the art may be employed without limitation. The adhesive member may be a pressure sensitive adhesive (“PSA”).

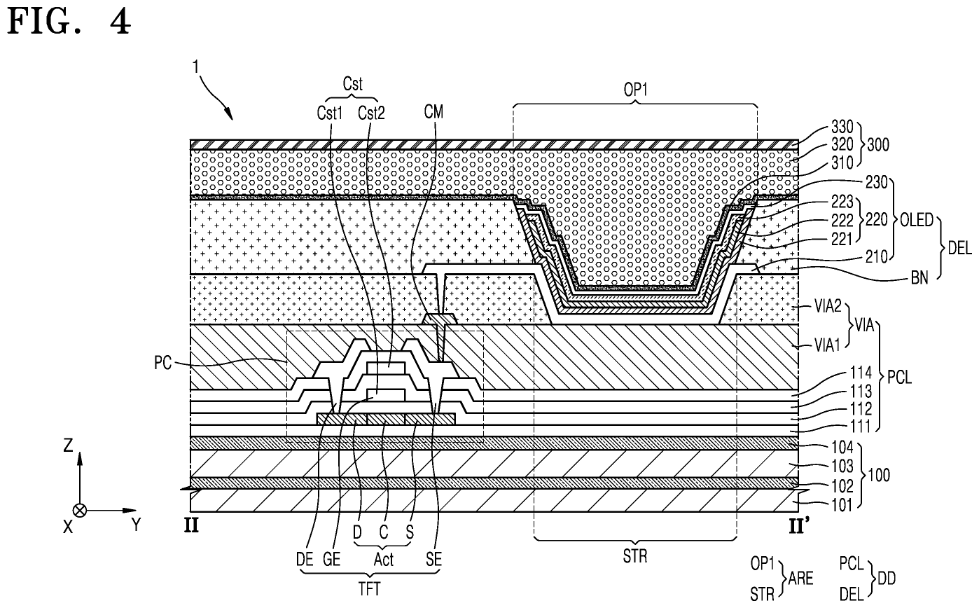

FIG. 4 is an enlarged view of another embodiment of the region A of FIG. 2.

In FIG. 4, descriptions that are the same as or similar to those described with reference to FIG. 3 are omitted, for convenience of description. In addition, the same reference numerals as those of FIG. 3 denote the same members, and thus, repeated descriptions thereof are omitted.

In FIG. 4, a second opening may be defined in the second planarization insulating layer VIA2 in the first structure STR compared to the embodiment described with reference to FIG. 3. That is, the first structure STR may pass through the second planarization insulating layer VIA2. At least a portion of the first electrode 210 disposed in the first structure STR may contact the first planarization insulating layer VIA1. In this structure, the height of the first space ARE may become greater. Accordingly, during a process of disposing the intermediate layer 220 in the first space ARE, a phenomenon in which the intermediate layer 220 overflows from the first space ARE may be further reduced.

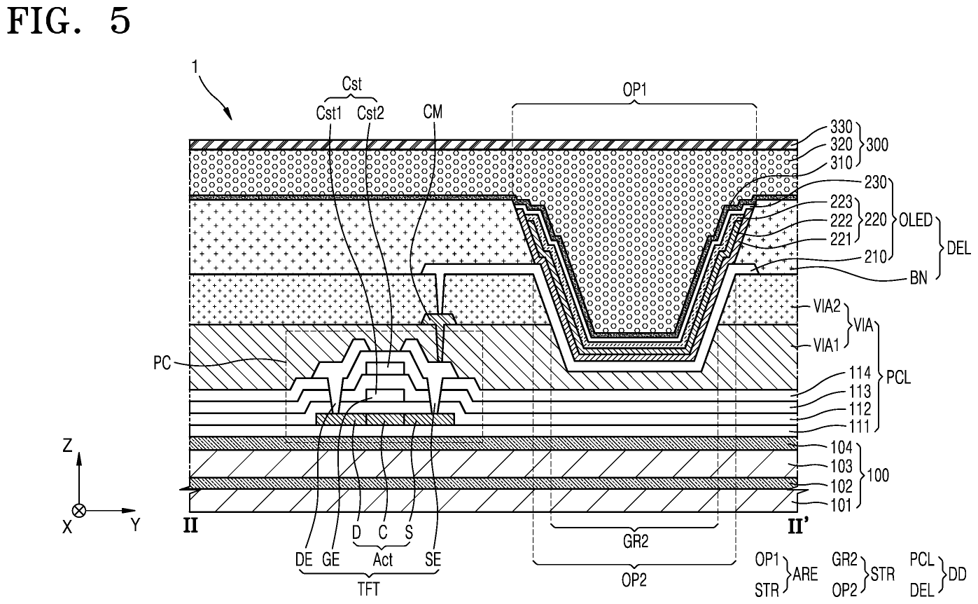

FIG. 5 is an enlarged view of another embodiment of the region A of FIG. 2.

In FIG. 5, descriptions that are the same as or similar to those described with reference to FIG. 4 are omitted, for convenience of description. In addition, the same reference numerals as those of FIG. 4 denote the same members, and thus, repeated descriptions thereof are omitted.

In FIG. 5, the first structure STR may further include a second groove GR2 defined in the first planarization insulating layer VIA1 compared to the embodiment described with reference to FIG. 4. The second groove GR2 may be defined by collapsing from the first planarization insulating layer VIA1. That is, the second groove GR2 may be defined in the first planarization insulating layer VIA1 and the second opening OP2 may be defined in the second planarization insulating layer VIA2 in the first structure STR.

At least a portion of the first electrode 210 disposed in the first structure STR may contact the first planarization insulating layer VIA1 or the second planarization insulating layer VIA2. In an embodiment, the first electrode 210 disposed in the second groove GR2 may contact the first planarization insulating layer VIA1, and the first electrode 210 disposed in the second opening OP2 may contact the second planarization insulating layer VIA2. In this structure, the height of the first space ARE may become greater. Accordingly, during a process of disposing the intermediate layer 220 in the first space ARE, a phenomenon in which the intermediate layer 220 overflows from the first space ARE may be further reduced.

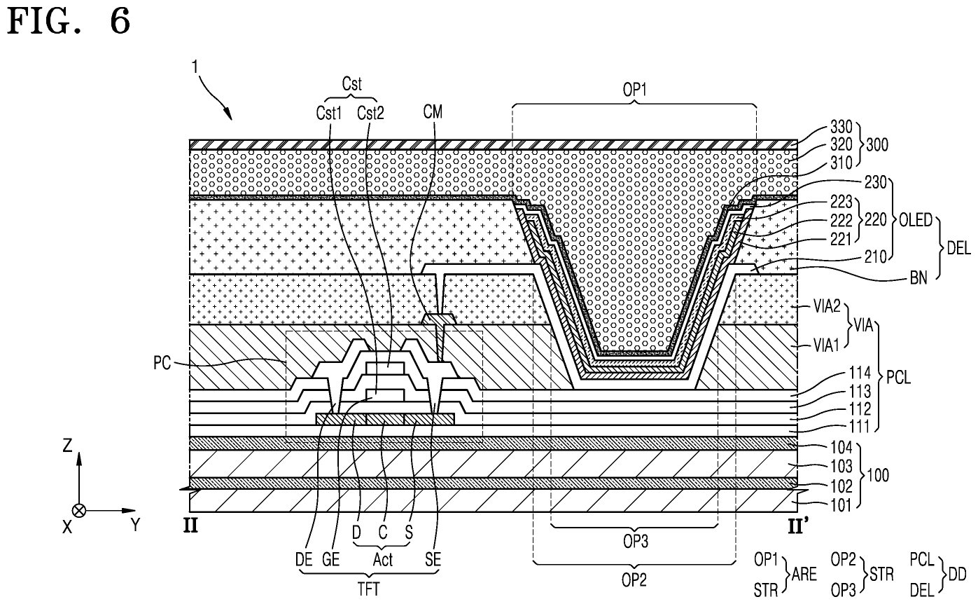

FIG. 6 is an enlarged view of another embodiment of the region A of FIG. 2.

In FIG. 6, descriptions that are the same as or similar to those described with reference to FIG. 5 are omitted, for convenience of description. In addition, the same reference numerals as those of FIG. 5 denote the same members, and thus, repeated descriptions thereof are omitted.

In FIG. 6, a third opening OP3 may be further in the first planarization insulating layer VIA1 in the first structure STR compared to the embodiment described with reference to FIG. 5. The third opening OP3 may pass through the first planarization insulating layer VIA1. That is, the third opening OP3 may be defined in the first planarization insulating layer VIA1 and the second opening OP2 may be defined in the second planarization insulating layer VIA2 in the first structure STR.

At least a portion of the first electrode 210 disposed in the first structure STR may contact the first planarization insulating layer VIA1 or the second planarization insulating layer VIA2. In an embodiment, the first electrode 210 disposed in the third opening OP3 may contact the first planarization insulating layer VIA1 or the inter-insulating layer 114, and the first electrode 210 disposed in the second opening OP2 may contact the second planarization insulating layer VIA2. In this structure, the height of the first space ARE may become higher. Accordingly, during a process of disposing the intermediate layer 220 in the first space ARE, a phenomenon in which the intermediate layer 220 overflows from the first space ARE may be further reduced.

In an embodiment, the height of the third opening OP3 may be about 2 μm or more, the height of the second opening OP2 may be about 2 μm or more, and the height of the first opening OP1 may be about 1.5 μm or more. However, this is an example, and the heights of the third opening OP3, the second opening OP2, and the first opening OP1 are not limited thereto.

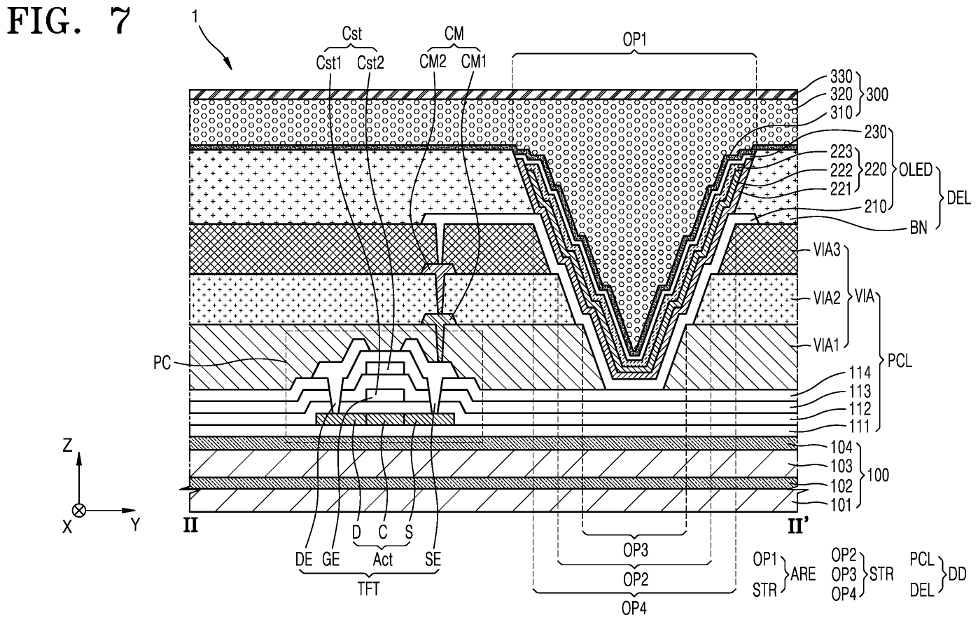

FIG. 7 is an enlarged view of another embodiment of the region A of FIG. 2.

In FIG. 7, descriptions that are the same as or similar to those described with reference to FIG. 3 are omitted, for convenience of description. In addition, the same reference numerals as those of FIG. 3 denote the same members, and thus, repeated descriptions thereof are omitted.

In FIG. 7, the planarization insulating layer VIA may further include a third planarization insulating layer VIA3 compared to the embodiment described with reference to FIG. 3. The third planarization insulating layer VIA3 may be disposed on the second planarization insulating layer VIA2. That is, the third planarization insulating layer VIA3 may be disposed between the second planarization insulating layer VIA2 and the bank layer BN. A fourth opening OP4 may be further defined in the third planarization insulating layer VIA3 in the first structure STR. The fourth opening OP4 may pass through the third planarization insulating layer VIA3. That is, the third opening OP3 may be defined in the first planarization insulating layer VIA1, the second opening OP2 may be defined in the second planarization insulating layer VIA2, and a fourth opening OP4 may be defined in the third planarization insulating layer VIA3 in the first structure STR.

At least a portion of the first electrode 210 may be disposed on the third planarization insulating layer VIA3. That is, at least a portion of the first electrode 210 may be disposed between the third planarization insulating layer VIA3 and the bank layer BN. In addition, at least a portion of the first electrode 210 may overlap the first structure STR. The first electrode 210 overlapping the first structure STR may be connected to the intermediate layer 220.

The contact metal CM connecting the first electrode 210 to the pixel circuit PC may include a first contact metal CM1 and a second contact metal CM2. At least a portion of the contact metal CM may be disposed between the first planarization insulating layer VIA1 and the second planarization insulating layer VIA2. The first contact metal CM1 may be connected to the pixel circuit PC through a contact hole defined in the first planarization insulating layer VIA1. At least a portion of the second contact metal CM2 may be disposed between the second planarization insulating layer VIA2 and the third planarization insulating layer VIA3. The second contact metal CM2 may be connected to the first contact metal CM1 through a contact hole defined in the second planarization insulating layer VIA2. In addition, the second contact metal CM2 may be connected to the first electrode 210 through a contact hole defined in the third planarization insulating layer VIA3. Consequently, the first contact metal CM1 and the second contact metal CM2 may connect the first electrode 210 to the pixel circuit PC.

At least a portion of the first electrode 210 disposed in the first structure STR may contact the first planarization insulating layer VIA1, the second planarization insulating layer VIA2, or the third planarization insulating layer VIA3. In an embodiment, the first electrode 210 disposed in the third opening OP3 may contact the first planarization insulating layer VIA1 or the inter-insulating layer 114, the first electrode 210 disposed in the second opening OP2 may contact the second planarization insulating layer VIA2, and the first electrode 210 disposed in the fourth opening OP4 may contact the third planarization insulating layer VIA3. In this structure, the height of the first space ARE may become higher. Accordingly, during a process of disposing the intermediate layer 220 in the first space ARE, a phenomenon in which the intermediate layer 220 overflows from the first space ARE may be further reduced.

Though it is shown in FIG. 7 that the third opening OP3, the second opening OP2, and the fourth opening OP4 are defined in the first structure STR, this is merely one of embodiments, and the first structure STR is not limited thereto. In an embodiment, the second groove GR2 (refer to FIG. 5), not the third opening OP3, may be defined in the first planarization insulating layer VIA1, and the first groove (refer to FIG. 3), not the second opening OP2, may be defined in the second planarization insulating layer VIA2. In addition, various combinations may be derived from the third opening OP3 or the second groove GR2 defined in the first planarization insulating layer VIA1, and the second opening OP2 or the first groove defined in the second planarization insulating layer VIA2.

The first space ARE may be spaced apart from the pixel circuit PC and the contact metal CM in a plan view. That is, the first space ARE may not overlap the pixel circuit PC and the contact metal CM. The first structure STR and the first opening OP1 may be spaced apart from the pixel circuit PC, the first contact metal CM1, and the second contact metal CM2 in a plan view. That is, the first structure STR and the first opening OP1 may not overlap the pixel circuit PC, the first contact metal CM1, and the second contact metal CM2. In this structure, a phenomenon in which the flatness of the first electrode 210 overlapping the intermediate layer 220 is reduced due to the pixel circuit PC and the contact metal CM, and other wirings may be reduced.

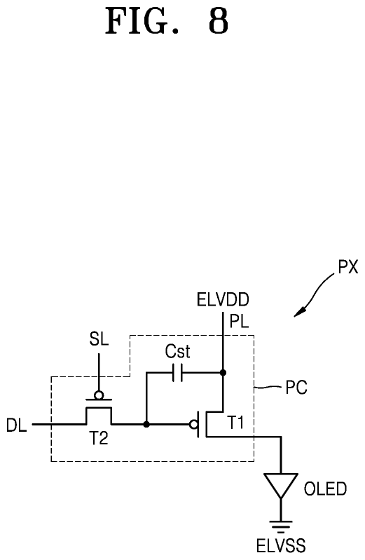

FIG. 8 is an equivalent circuit diagram of a pixel of the display apparatus.

Each pixel PX may include the pixel circuit PC and a display element connected to the pixel circuit PC. The display element may be, e.g., an organic light-emitting diode OLED. The pixel circuit PC may include a first thin-film transistor T1, a second thin-film transistor T2, and a storage capacitor Cst. Each pixel PX may emit various color lights such as red, green, blue, or white light from the organic light-emitting diode OLED.

The second thin-film transistor T2 is a switching thin-film transistor, may be connected to a scan line SL and a data line DL, and may transfer a data voltage, which is input from the data line DL, to the first thin-film transistor T1 based on a switching voltage, which is input from the scan line SL. The storage capacitor Cst may be connected to the second thin-film transistor T2 and a driving voltage line PL and may store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and may control a driving current according to the voltage stored in the storage capacitor Cst, the driving current flowing from the driving voltage line PL to the organic light-emitting diode OLED. The organic light-emitting diode OLED may emit light having a preset brightness corresponding to the driving current. The second electrode 230 (refer to FIG. 3) of the organic light-emitting diode OLED may receive a second power voltage ELVSS.

Though it is described with reference to FIG. 8 that the pixel circuit PC includes two thin-film transistors and one storage capacitor, the disclosure is not limited thereto. The number of thin-film transistors and the number of storage capacitors may be variously changed according to the design of the pixel circuit PC. In an embodiment, the pixel circuit PC may further include four or more thin-film transistors as well as the two thin-film transistors.

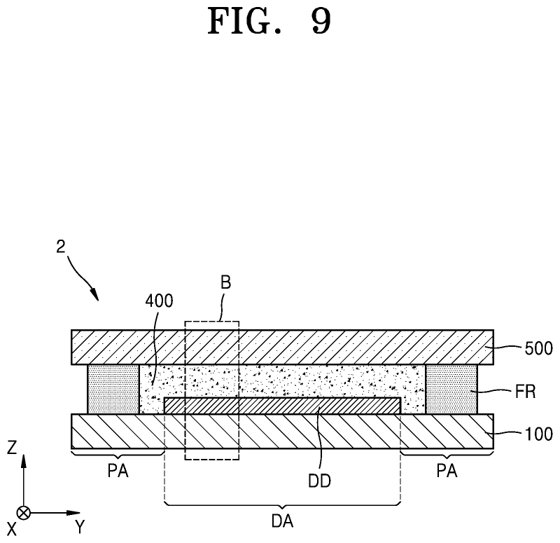

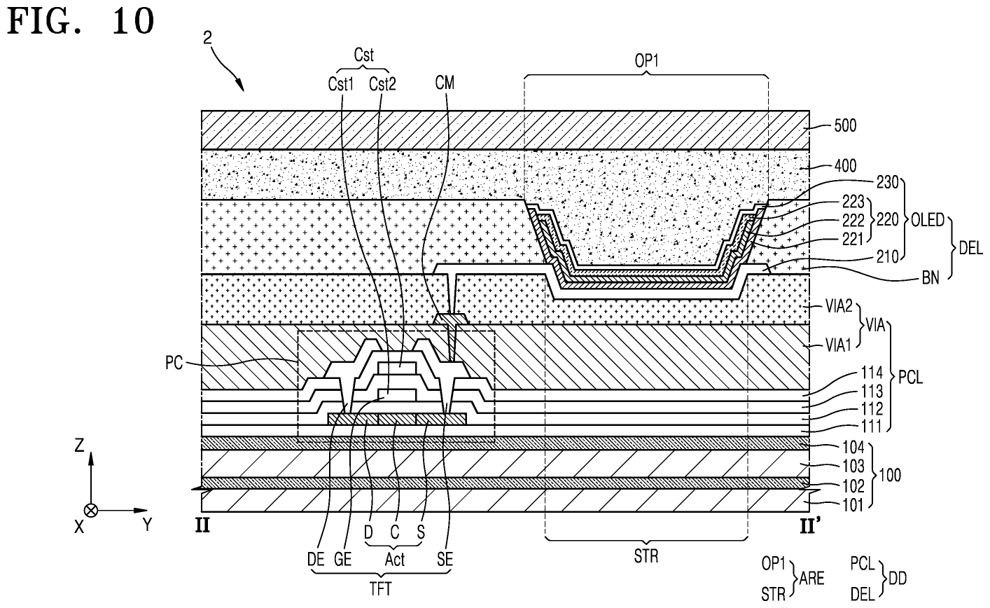

FIG. 9 is a cross-sectional view of another embodiment of a display apparatus 2, taken along line II-II′ of FIG. 1, and FIG. 10 is an enlarged view of an embodiment of the display apparatus 2.

In FIGS. 9 and 10, descriptions that are the same as or similar to those described with reference to FIGS. 1 to 8 are omitted, for convenience of description. In addition, in FIGS. 9 and 10, the same reference numerals as those of FIGS. 1 to 8 denote the same members, and thus, repeated descriptions thereof are omitted.

Referring to FIGS. 9 and 10, the display apparatus 2 may include the substrate 100, the display portion DD disposed on the substrate 100, a cover substrate 500 facing the substrate 100, a sealing member FR bonding the substrate 100 to the cover substrate 500, and an intermediate member 400 disposed between the substrate 100 and the cover substrate 500.

The cover substrate 500 may be disposed over the substrate 100 on which the display portion DD is provided. The cover substrate 500 may be disposed over the display portion DD to face the substrate 100 and bonded to the substrate 100 through the sealing member FR described below.

The cover substrate 500 may be the substrate 100 having a substantially high rigidity. In an embodiment, the cover substrate 500 may include a transparent glass material including or consisting of SiO₂ as a main component. However, this is an example, and the cover substrate 500 may include at least one of a metal, a plastic, and an acrylic material.

The sealing member FR may be disposed in the peripheral area PA of the substrate 100. Through this, the substrate 100 may be bonded to the cover substrate 500. The sealing member FR may be apart by a preset interval from the display portion DD disposed in the display area DA, and also apart in an inner side apart by a preset interval from the outside of the substrate 100. The sealing member FR may include glass frit, for example. As described above, the sealing member FR may bond the substrate 100 to the cover substrate 500, and through this, the display portion DD may be sealed from the outside.

The intermediate member 400 may be disposed in a space defined by the cover substrate 500 and the sealing member FR. The intermediate member 400 may contact the substrate 100, the upper surface (e.g., the surface facing a +Z axis) of the display portion DD, the inner surface of the sealing member FR, and the lower surface (e.g., the surface facing a −Z axis) of the cover substrate 500. The intermediate member 400 may compensate for a degree of refraction of light while the light emitted from the display portion DD propagates to the outside of the display apparatus 2. At least a portion of the intermediate member (also referred to as an intermediate layer) 400 may be disposed on the organic light-emitting diode OLED of the display element layer DEL. In an embodiment, at least a portion of the intermediate layer 400 may contact the bank layer BN or the second electrode 230.

By embodiments, a phenomenon in which the emission layer overflows from the opening of the bank layer may be reduced, and the flatness of the first electrode on which the intermediate layer is disposed may be improved.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a substrate;
a pixel circuit disposed on the substrate;
a planarization insulating layer which is disposed on the pixel circuit and including a first structure in which an opening or a groove is defined;
a bank layer which is disposed on the planarization insulating layer and in which a first opening overlapping the first structure is defined; and
an intermediate layer disposed in at least a portion of the first structure and the first opening.

2. The display apparatus of claim 1, wherein the first structure and the first opening are spaced apart from the pixel circuit in a plan view.

3. The display apparatus of claim 1, wherein the planarization insulating layer comprises:
a first planarization insulating layer; and
a second planarization insulating layer on the first planarization insulating layer.

4. The display apparatus of claim 3, wherein a first groove is defined in the second planarization insulating layer in the first structure.

5. The display apparatus of claim 3, wherein a second opening is defined in the second planarization insulating layer in the first structure.

6. The display apparatus of claim 5, wherein a second groove overlapping the second opening is defined in the first planarization insulating layer in the first structure.

7. The display apparatus of claim 5, wherein a third opening overlapping the second opening is defined in the first planarization insulating layer in the first structure.

8. The display apparatus of claim 3, further comprising:
a first electrode connected to the intermediate layer and including at least a portion disposed between the second planarization insulating layer and the bank layer; and
a contact metal connecting the first electrode to the pixel circuit and including at least a portion disposed between the first planarization insulating layer and the second planarization insulating layer,
wherein the first structure and the first opening are spaced apart from the contact metal in a plan view.

9. The display apparatus of claim 3, wherein the planarization insulating layer further comprises a third planarization insulating layer on the second planarization insulating layer.

10. The display apparatus of claim 9, wherein a fourth opening is defined in the third planarization insulating layer in the first structure.

11. A display apparatus comprising:
a substrate;
a pixel circuit disposed on the substrate;
a planarization insulating layer disposed on the pixel circuit;
a bank layer disposed on the planarization insulating layer; and
an intermediate layer disposed in a first space disposed in the planarization insulating layer and the bank layer.

12. The display apparatus of claim 11, wherein the first space is spaced apart from the pixel circuit in a plan view.

13. The display apparatus of claim 11, wherein the planarization insulating layer comprises:
a first planarization insulating layer; and
a second planarization insulating layer on the first planarization insulating layer.

14. The display apparatus of claim 13, wherein the first space comprises:
a first opening defined in the bank layer; and
a first groove overlapping the first opening and defined in the second planarization insulating layer.

15. The display apparatus of claim 14, wherein the first space comprises:
the first opening defined in the bank layer; and
a second opening overlapping the first opening and defined in the second planarization insulating layer.

16. The display apparatus of claim 15, wherein the first space further comprises a second groove overlapping the second opening and defined in the first planarization insulating layer.

17. The display apparatus of claim 15, wherein the first space further comprises a third opening overlapping the second opening and defined in the first planarization insulating layer.

18. The display apparatus of claim 13, wherein the planarization insulating layer further comprises a third planarization insulating layer on the second planarization insulating layer.

19. The display apparatus of claim 18, wherein the first space comprises:
a first opening defined in the bank layer; and
a fourth opening overlapping the first opening and defined in the third planarization insulating layer.

20. The display apparatus of claim 13, further comprising:
a first electrode connected to the intermediate layer and including at least a portion disposed between the second planarization insulating layer and the bank layer; and
a contact metal connecting the first electrode to the pixel circuit and including at least a portion disposed between the first planarization insulating layer and the second planarization insulating layer,
wherein the first space is spaced apart from the contact metal in a plan view.
